(19) United States
(12) Patent Application Publication
(10) Pub. No.: US 2025/0309059 A1
(43) Pub. Date: Oct. 2, 2025

(54) SEMICONDUCTOR DEVICE AND METHOD

(71) Applicant: Taiwan Semiconductor Manufacturing Co., Ltd., Hsinchu (TW)

(72) Inventors: Yang-Hsin Shih, Hsinchu (TW); Kuan-Hsun Wang, Hsinchu (TW); Chih Hsin Yang, Zhubei City (TW)

(21) Appl. No.: 19/237,430

(22) Filed: Jun. 13, 2025

Related U.S. Application Data
(63) Continuation of application No. 18/403,146, filed on Jan. 3, 2024.
(60) Provisional application No. 63/520,717, filed on Aug. 21, 2023.
(60) Provisional application No. 63/607,852, filed on Dec. 8, 2023.

(51) Int. Cl. H01L 23/48; H01L 21/768; H01L 23/00; H01L 23/522; H01L 23/58

(52) U.S. Cl. CPC H01L 23/481; H01L 21/76898; H01L 23/5226; H01L 23/585; H01L 24/08; H01L 24/80; H01L 24/81; H01L 2224/08145; H01L 2224/80895; H01L 2224/80896; H01L 2224/81

(57) ABSTRACT

An embodiment includes a device, the device including a first die including a first surface and a second surface opposite the first surface. The first die includes a plurality of through substrate vias (TSVs) exposed from the second surface of the first die. The device also includes a guard ring surrounding the plurality of TSVs. The device also includes a dummy metallization pattern surrounding the guard ring. The device also includes an active metallization pattern connected to active devices in the first die.

### PRIORITY CLAIM AND CROSS-REFERENCE

This application is a continuation of U.S. patent application Ser. No. 18/403,146, filed Jan. 3, 2024, which claims the benefit of U.S. Provisional Application No. 63/607,852, filed Dec. 8, 2023, entitled “SEMICONDUCTOR DEVICE AND METHOD,” and U.S. Provisional Application No. 63/520,717 filed on Aug. 21, 2023 entitled “TSV OPTIMIZED CLUSTER FOR HIGH PPAC,” which applications are hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged. An example of such packaging systems is Package-on-Package (POP) technology. In a POP device, a top semiconductor package is stacked on top of a bottom semiconductor package to provide a high level of integration and component density. PoP technology generally enables production of semiconductor devices with enhanced functionalities and small footprints on a printed circuit board (PCB).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 2, 3, 4, 5, 6A, 6B, 6C, 7, 8, and 9 illustrate cross-sectional views and plan views of intermediate stages in the formation of a die according to embodiments.

FIGS. 10 through 14 illustrate cross-sectional views of intermediate stages in the formation of a package according to embodiments.

FIGS. 15A, 15B, 15C, and 15D illustrate cross-sectional views and plan views of intermediate stages in the formation of a die according to embodiments.

FIG. 16 illustrates a cross-sectional view of a package according to embodiments.

FIG. 17 illustrates a cross-sectional view of a package according to embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments discussed herein may be discussed in a specific context, namely a through substrate via (TSV) cluster that has reduced pitch between adjacent TSVs. In some embodiments, the TSV cluster has a merged guard ring wall between adjacent TSVs. In some embodiments, a dummy interconnect structure is between adjacent TSVs of the TSV cluster instead of the merged guard ring wall. By having the merged guard ring wall or the dummy interconnect structure between adjacent TSVs of the TSV cluster, the pitch between adjacent TSVs can be reduced. Thus, the total area consumed by the TSV cluster is reduced and more area can be used for other functionality of the device, or the device size can be reduced. In some embodiments, the disclosed TSV cluster may be applied to a device (e.g., a chip or die) or a package (e.g., system on integrated chip (SoIC), a chip-on-wafer (CoW) package structure, or a wafer-on-wafer (WoW) package structure). By reducing the pitch between the adjacent TSVs in a TSV cluster, the performance, power, and area cost of the device is improved. For example, in a 2×2 TSV cluster, the area cost with the disclosed TSV cluster is reduced by 25%-35% as compared to a conventional TSV structure.

Further, the teachings of this disclosure are applicable to any device or package with a TSV cluster. Other embodiments contemplate other applications, such as different package types or different configurations that would be readily apparent to a person of ordinary skill in the art upon reading this disclosure. It should be noted that embodiments discussed herein may not necessarily illustrate every component or feature that may be present in a structure. For example, multiples of a component may be omitted from a figure, such as when discussion of one of the components may be sufficient to convey aspects of the embodiment. Further, method embodiments discussed herein may be discussed as being performed in a particular order; however, other method embodiments may be performed in any logical order.

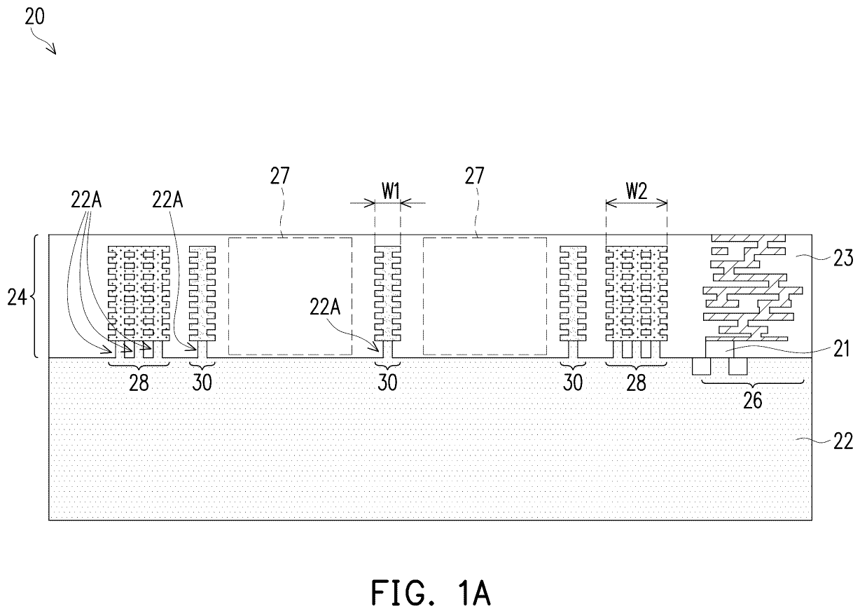

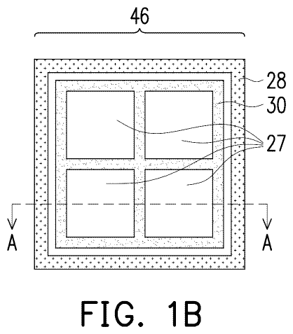

FIGS. 1A, 1B, 2, 3, 4, 5, 6A, 6B, 6C, 7, 8, and 9 illustrate cross-sectional views and plan views of intermediate stages in the formation of a die in accordance with some embodiments.

FIG. 1A illustrates a cross-sectional of an integrated circuit die 20 in accordance with some embodiments. FIG. 1B illustrates a plan view of the structure in FIG. 1B with FIG. 1A being along the line A-A in FIG. 1B. The integrated circuit die 20 will be packaged in subsequent processing to form an integrated circuit package. The integrated circuit die 20 may be a logic die (e.g., central processing unit (CPU), graphics processing unit (GPU), system-on-a-chip (SoC), application processor (AP), microcontroller, etc.), a memory die (e.g., dynamic random access memory (DRAM) die, static random access memory (SRAM) die, etc.), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof.

The integrated circuit die 20 may be formed in a wafer, which may include different device regions that are singulated in subsequent steps to form a plurality of integrated circuit dies. The integrated circuit die 20 may be processed according to applicable manufacturing processes to form integrated circuits. For example, the integrated circuit die 20 includes a substrate 22, such as silicon, doped or undoped, or an active layer of a semiconductor-on-insulator (SOI) substrate. The substrate 22 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multi-layered or gradient substrates, may also be used. The substrate 22 has an active surface (e.g., the surface facing upwards in FIG. 1A), sometimes called a front side, and an inactive surface (e.g., the surface facing downwards in FIG. 1A), sometimes called a back side.

Devices 21 may be formed at the front surface of the substrate 22. The devices 21 may be active devices (e.g., transistors, diodes, etc.), capacitors, resistors, the like, or a combination thereof. An inter-layer dielectric (ILD) (not separately illustrated) is over the front surface of the substrate 22. The ILD surrounds and may cover the devices 21. The ILD may include one or more dielectric layers formed of materials such as Phospho-Silicate Glass (PSG), Boro-Silicate Glass (BSG), Boron-Doped Phospho-Silicate Glass (BPSG), Undoped Silicate Glass (USG), or the like.

Conductive plugs (not separately illustrated) extend through the ILD to electrically and physically couple the devices 21. For example, when the devices 21 are transistors, the conductive plugs may couple the gates and source/drain regions of the transistors. The conductive plugs may be formed of tungsten, cobalt, nickel, copper, silver, gold, aluminum, the like, or combinations thereof.

The active surface of the substrate 22 includes portions 22A between the substrate 22 and dummy metallization pattern 28 and the guard ring 30. These portions 22A may be patterned portions of the substrate 22 or may be structures formed on top of the substrate 22. These portions extend as high as the front-end-of-line processing of the substrate 22. In some embodiments, the front-end-of-line processing ends after the gate, ILD, and conductive plug formation.

An interconnect structure 24 is over the ILD and the conductive plugs. The interconnect structure 24 may be formed by, for example, metallization patterns 26, 28, 30 in dielectric layers 23 on the ILD. In these embodiments, the metallization patterns 26, 28, 30 are formed in the middle-end-of line and the back-end-of line processing. The metallization patterns 26, 28, 30 include metal lines and vias formed in one or more low-k dielectric layers 23. The metallization patterns may be formed using any suitable process, such as a single damascene process, a dual damascene process, a plating process, combinations thereof, or the like.

The metallization patterns 26, 28, 30 include active metallization patterns 26, dummy metallization patterns 28, and guard rings 30. The active metallization patterns 26 of the interconnect structure 24 interconnects the devices to form an integrated circuit. The active metallization patterns 26 are electrically coupled to the devices by the conductive plugs. The dummy metallization pattern 28 is electrically isolated from the devices of the die 20.

As illustrated in FIGS. 1A and 1B, the dummy metallization patterns 28 and the guard rings 30 are formed around TSV areas 27. In FIG. 1B, there is illustrated a group of four TSV areas 27 and may be referred to as a TSV cluster 46. The dummy metallization patterns 28 and the guard rings 30 are formed simultaneously and by the same processes as the active metallization patterns 26. The guard rings 30 can reduce the leakage current between the subsequently formed TSVs and the substrate 22 and other structures in the interconnect structure 24. In addition, TSVs can introduce mechanical stress and the guard rings 30 can provide stress relief during the fabrication and operation of the device. Further, the guard rings 30 can provide electrical isolation between the TSVs and nearby active devices and metallization patterns. The dummy metallization patterns 28 are included to provide a more uniform pattern density in the interconnect structure 24 which can help with planarization and process consistency, such as during a chemical mechanical polishing (CMP) process.

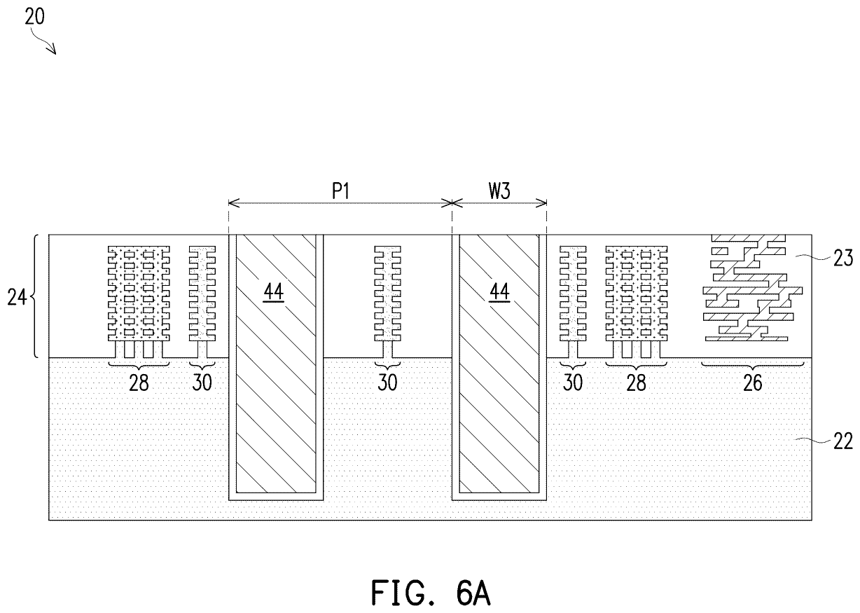

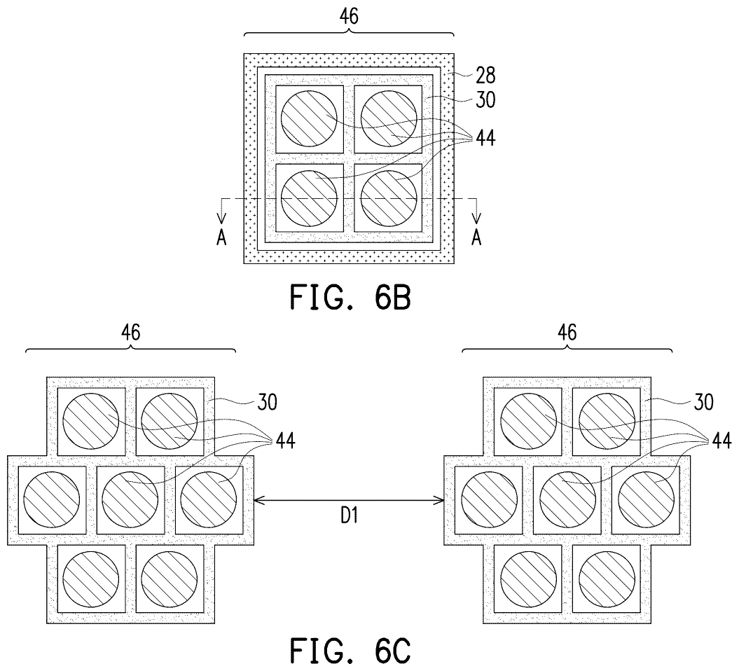

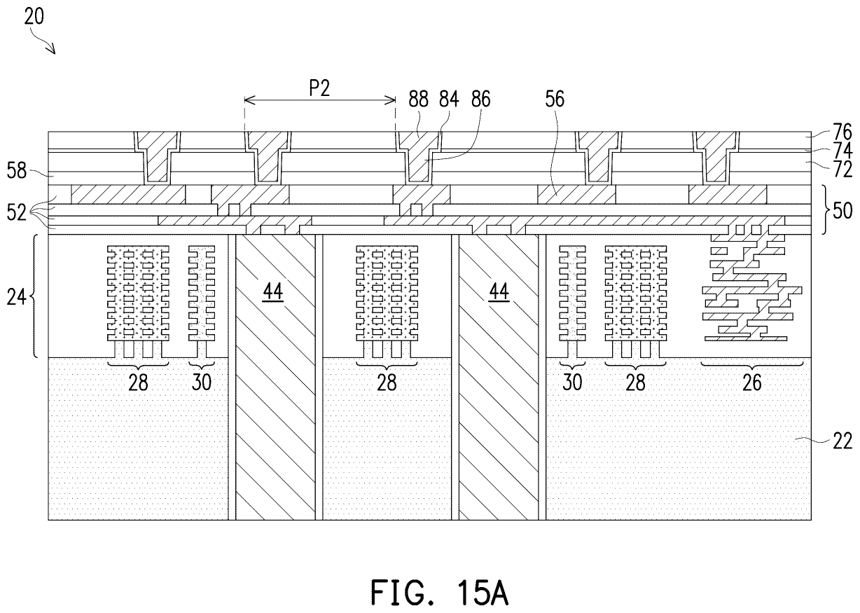

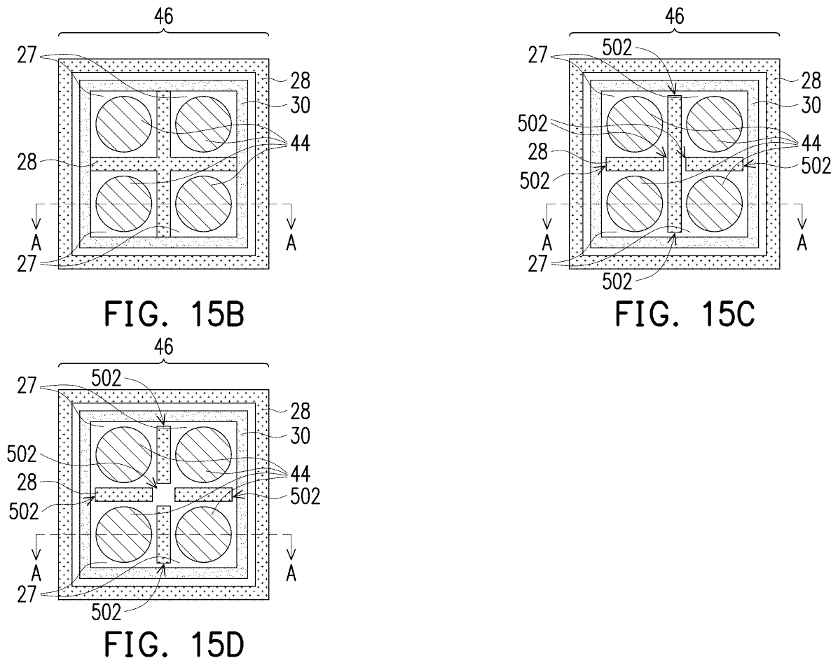

In some embodiments, the guard rings 30 surround and are between each of the TSV areas 27 and the dummy metallization patterns 28 surround the guard rings 30 and are not between the TSV areas 27 (see, e.g., FIG. 1B and 6B). In some embodiments, the dummy metallization patterns are between the TSV areas 27 and the guard rings surround the TSV areas 27 and are not between the TSV areas 27 (see, e.g., FIGS. 15B, 15C, and 15D). In some embodiments, the guard ring 30 are formed to have a width W1 and the dummy metallization patterns are formed to have a width W2. In some embodiments, the width W1 is in a range from 0.5 μm to 1.5 μm. In some embodiments, the width W2 is at least 0.5 μm and can be as wide as needed for the design of the device. For example, the width W2 of the dummy metallization patterns 28 may only be limited by the distance between the guard ring 30 and the nearest active metallization pattern 26 such that the dummy metallization 28 has a width to fill that distance. In some embodiments, the width W2 can be greater than 10 μm or greater than 40 μm.

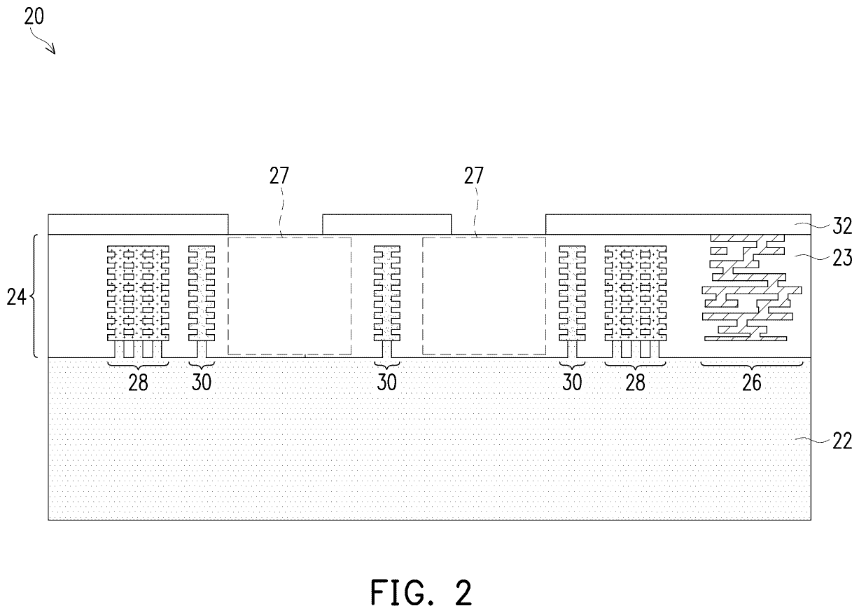

After forming the interconnect structure 24, as shown in FIG. 2, a mask 32 is formed and patterned on the interconnect structure 24. In some embodiments, the mask 32 is a photoresist and may be formed by spin coating or the like and may be exposed to light for patterning. The pattern of the photoresist corresponds to the subsequently formed through substrate via (TSV) 44 (see, e.g., FIG. 6A) in the TSV areas 27. The patterning forms at least one opening through the photoresist 32 to expose the interconnect structure 24. In some embodiments, a stop layer (not shown), such as a chemical mechanical polishing (CMP) stop layer is deposited over a top surface of the interconnect structure 24 before the mask 32. The CMP stop layer may be used to prevent a subsequent CMP process from removing too much material by being resistant to the subsequent CMP process and/or by providing a detectable stopping point for the subsequent CMP process. In some embodiments, the CMP stop layer may comprise one or more layers of dielectric materials. Suitable dielectric materials may include oxides (such as silicon oxide, aluminum oxide, or the like), nitrides (such as SiN, or the like), oxynitrides (such as SiON, or the like), oxycarbides (such as SiOC, or the like), carbonitrides (such as SiCN, or the like), carbides (such as SiC, or the like), combinations thereof, or the like, and may be formed using spin-on coating, chemical vapor deposition (CVD), plasma-enhanced CVD (PECVD), atomic layer deposition (ALD), the like, or a combination thereof.

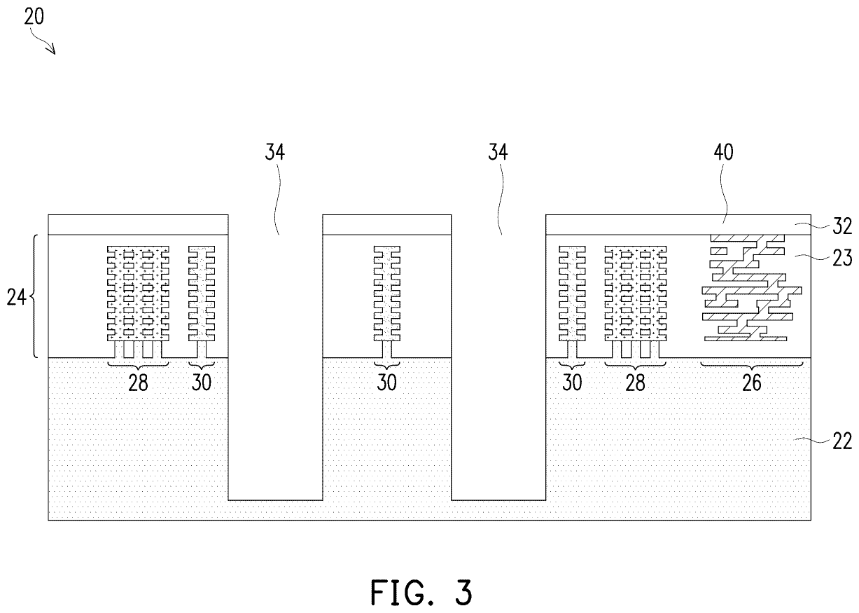

In FIG. 3, the remaining mask 32 is used as a mask during an etching process to remove exposed and underlying portions of the dielectric layer(s) 23 of the interconnect structure 24 and the substrate 22. A single etch process may be used to etch openings 34 in the TSV areas 27 of the interconnect structure 24 and the substrate 22 or a first etch process may be used to etch the interconnect structure 24 and a second etch process may be used to etch the substrate 22. In some embodiments, the opening 34 is formed with a plasma dry etch process, and a reactive ion etch (RIE) process, such as a deep RIE (DRIE) process. In some embodiments, the DRIE process includes etch cycle(s) and passivation cycle(s) with the etch cycle(s) using, for example, SF₆, and the passivation cycle(s) using, for example, C₄F₈. The utilization of a DRIE process with the passivation cycle(s) and the etch cycle(s) enables a highly anisotropic etching process. In some embodiments, the etch process(es) may be any acceptable etching process, such as by wet or dry etching.

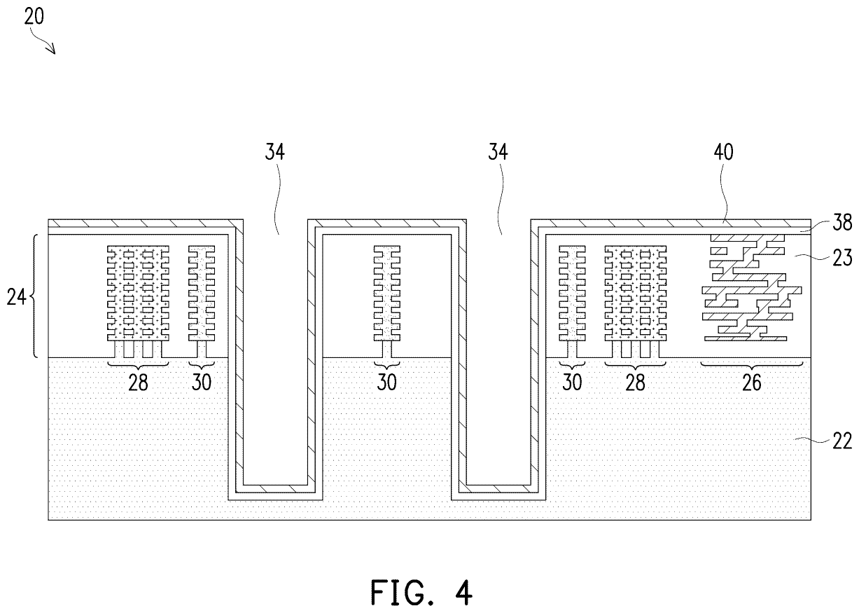

As illustrated in FIG. 4, after forming the openings 34, the photoresist 32 is removed. The photoresist 32 may be removed by an acceptable ashing or stripping process, such as using an oxygen plasma or the like.

Further in FIG. 4, a liner layer 38 is conformally deposited on the interconnect structure 24 and on bottom surfaces and sidewalls of the openings 34. In some embodiments, the liner layer 38 includes one or more layers of dielectric materials and may be used to physically and electrically isolate the subsequently formed through vias from the substrate 22. Suitable dielectric materials may include oxides (such as silicon oxide, aluminum oxide, or the like), nitrides (such as SiN, or the like), oxynitrides (such as SiON, or the like), combinations thereof, or the like. The liner layer 38 may be formed using CVD, PECVD, ALD, the like, or a combination thereof.

In a subsequent step, as shown in FIG. 4, a seed layer 40 is formed over liner layer 38. In some embodiments, the seed layer 40 is a metal layer, which may be a single layer or a composite layer comprising a plurality of sub-layers formed of different materials. In some embodiments, the seed layer 40 comprises a titanium layer and a copper layer over the titanium layer. The seed layer may be formed using, for example, physical vapor deposition (PVD) or the like. In some embodiments, a barrier layer (not shown) may be formed on the liner layer 38 prior to forming the seed layer 40. The barrier layer may comprise Ti, TiN, the like, or a combination thereof.

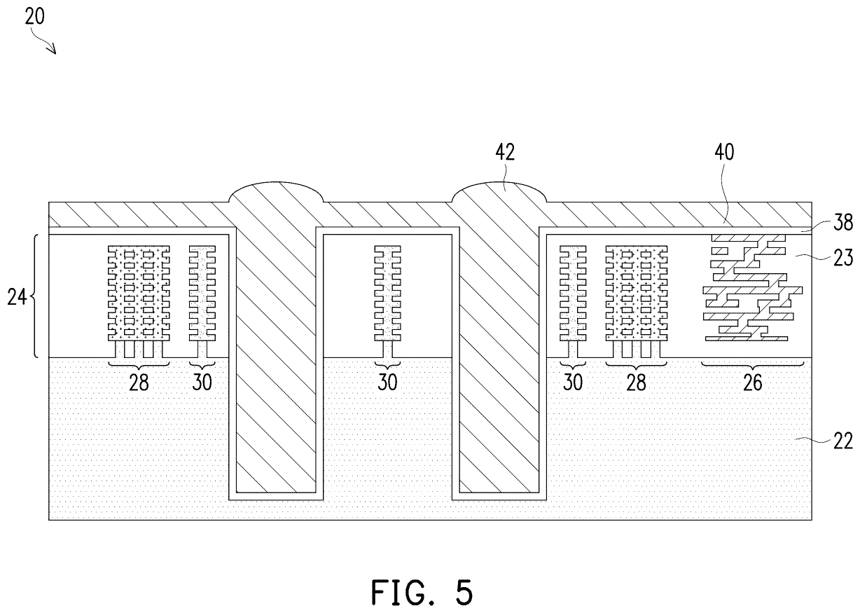

In FIG. 5, a conductive material 42 is formed on the seed layer 40 and fills the openings 34. The conductive material 42 may be formed by plating, such as electroplating including electrochemical plating, electroless plating, or the like. The conductive material may comprise a metal, like copper, titanium, tungsten, aluminum, or the like.

After the conductive material 42 is formed, an anneal process is then performed. The anneal process may be performed to prevent subsequent extrusion of the conductive material of the TSV 44 (sometime referred to as TSV pumping). The TSV pumping is caused by a coefficient of thermal expansion (CTE) mismatch between the conductive material 42 and the substrate 22 and can cause damage to structures (e.g., metallization patterns) over the TSV.

Following the anneal process, a planarization process is performed to remove portions of the conductive material 42, the seed layer 40, and the liner layer 38 outside the openings 34 to form TSVs 44 as illustrated in FIG. 6A. Top surfaces of the TSV 44 and the topmost dielectric layer of the interconnect structure 24 are coplanar after the planarization process within process variations. The planarization process may be, for example, a chemical-mechanical polish (CMP), a grinding process, or the like. In some embodiments, the upper portion of the TSV 44 (formed in the interconnect structure 24) has a greater width than the lower portion of the TSV 44 (formed in the substrate 22). In some embodiments, the width of the TSV 44 is constant through the interconnect 24 and the substrate 22. In some embodiments, the TSVs 44 are formed to have a width W3. In some embodiments, the width W3 is in a range from 2 μm to 4.5 μm. In some embodiments, the TSVs 44 in a TSV cluster 46 are formed to have a pitch P1. In some embodiments, the pitch P1 is in a range from (1×W3) to (2×W3). In some embodiments, the pitch P1 is in a range from 4 μm to 5 μm.

FIG. 6B illustrates a plan view of the structure in FIG. 6A with FIG. 6A being along the line A-A in FIG. 6B. FIG. 6C illustrates a plan view of multiple TSV clusters 46. In the illustrated embodiment, the guard rings 30 surround and are between each of the TSVs 44 and the dummy metallization patterns 28 surround the guard rings 30 and are not between the TSVs 44. The guard rings 30 in FIG. 6B may be referred to as merged guard rings 30 as the guard rings are connected together and are not separated guard ring structures. Said another way, the guard rings 30 surrounding each of the TSVs 44 in the TSV cluster 46 is a continuous guard ring 30. In some embodiments, the TSV clusters 46 are separated by a distance D1. In some embodiments, the distance D1 is a minimum of 6 μm. In some embodiments, the distance Di is in a range from 6 μm to 150 μm. The merged guard rings 30 allow for a smaller distance D1 than conventional TSV structures.

Although FIG. 6B illustrates TSV clusters 46 with four TSVs 44 and FIG. 6C illustrates TSV clusters 46 with seven TSVs 44, these embodiments are not limited to those numbers of TSVs 44 per TSV cluster 46 and each may have more or less TSVs 44 per TSV cluster.

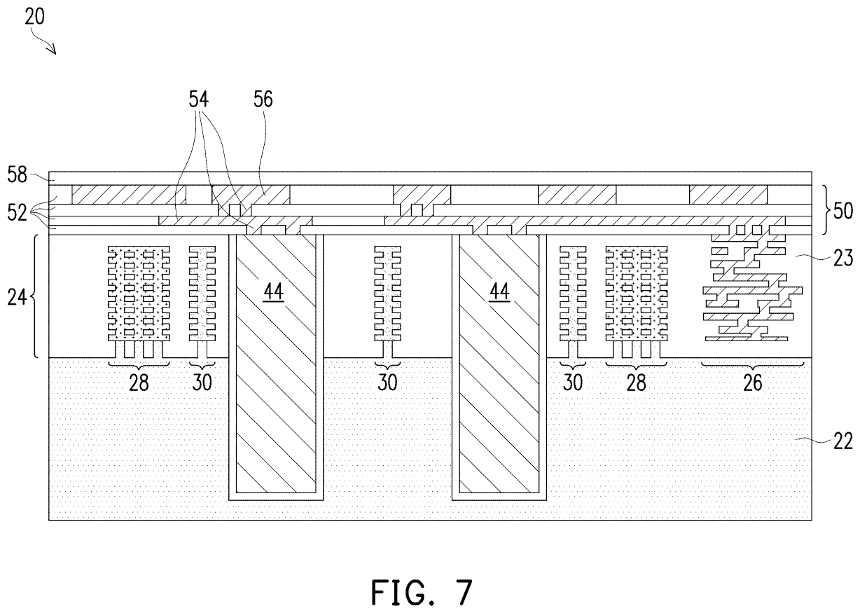

Referring to FIG. 7, an interconnect structure 50 is formed over the structure of FIG. 6A. The interconnect structure 50 includes dielectric layers 52, metallization patterns and vias 54, and top metal 56. More or fewer dielectric layers and metallization patterns and vias may be formed than is shown in FIG. 7. The interconnect structure 50 is connected to the active metallization patterns 26 of the interconnect structure 24 and TSV 44 by metallization patterns and vias formed in the dielectric layer(s) 52. The metallization patterns and vias may be formed similar processes and materials as the interconnect structure 24 and the description is not repeated herein. In some embodiments, there are more than one layer of top metal 56, such as two top metal layers.

In some embodiments, the dielectric layers 52 are a same material as the dielectric layers 23 of the interconnect structure 24, e.g., low-k dielectric. In other embodiments, the dielectric layers 52 are formed of a silicon-containing material (which may or may not include oxygen). For example, the dielectric layers 52 may include an oxide such as silicon oxide, a nitride such as silicon nitride, or the like.

The metallization patterns and vias 54 and the top metal 56 may be formed using any suitable process, such as a single damascene process, a dual damascene process, a plating process, combinations thereof, or the like. An example of forming the metallization patterns and vias 54 and the top metal 56 by a damascene process includes etching dielectric layers 52 to form openings, depositing a conductive barrier layer into the openings, plating a metallic material such as copper or a copper alloy, and performing a planarization to remove the excess portions of the metallic material. In other embodiments, the formation of the dielectric layers 52, the metallization patterns and vias 54, and the top metal 56 may include forming the dielectric layer 52, patterning the dielectric layer 52 to form openings, forming a metal seed layer (not shown), forming a patterned plating mask (such as photoresist) to cover some portions of the metal seed layer, while leaving other portions exposed, plating the metallization patterns and vias 54 and the top metal 56, removing the plating mask, and etching undesirable portions of the metal seed layer. The metallization patterns and vias 54 and top metal 56 may be made of tungsten, cobalt, nickel, copper, silver, gold, aluminum, the like, or combinations thereof. In some embodiments, the top metal 56 is thicker than the metallization patterns 54, such as three times thicker, five times thicker, or any suitable thickness ratio between the metallization layers.

FIG. 7 further illustrates the formation of a passivation layer 58 over the dielectric layers 52 and the top metal 56. In some embodiments, the passivation layer 58 is formed of a same material as the dielectric layers 52. In some embodiments, the passivation layer 58 may be a polymer such as polybenzoxazole (PBO), polyimide, benzocyclobutene (BCB), or the like; a nitride such as silicon nitride or the like; an oxide such as silicon oxide, phosphosilicate glass (PSG), borosilicate glass (BSG), boron-doped phosphosilicate glass (BPSG), or the like; the like; or a combination thereof. The passivation layer 58 may be formed, for example, by spin coating, lamination, chemical vapor deposition (CVD), or the like. The passivation layer 58 may have an upper surface that is level within process variations.

Although FIG. 7 illustrates the TSVs 44 directly connected to the interconnect structure 50, in some embodiments, one or more of the TSVs 44 may be directly connected to the interconnect 24.

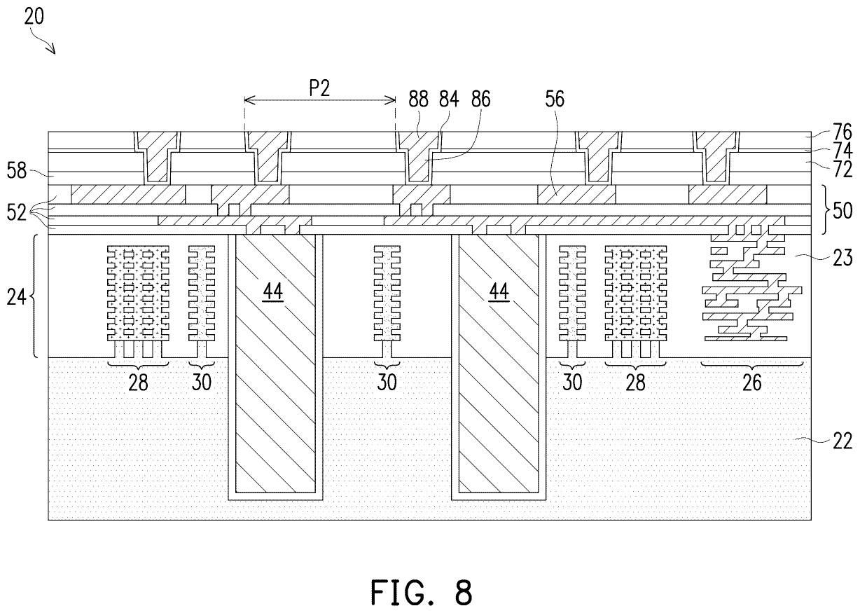

In FIG. 8, dielectric layers 72, 74, and 76 are formed over the passivation layer 58. Although FIG. 8 illustrates three dielectric layers 72, 74, and 76, more or fewer than three dielectric layers may be formed. The dielectric layer 72 is separated from the top metal structures 56A by the passivation layer 58. The dielectric layer 72 provides a planar top surface to form the dielectric layers 74 and 76 on and may be considered a planarization dielectric layer 72. The dielectric layer 74 may provide etch stop functions during subsequent formation of bond pads and bond vias and may be considered an etch stop layer 74. The dielectric layer 76 may provide dielectric bonding functions and may be considered a bonding dielectric layer 76.

In some embodiments, the dielectric layers 72, 74, and 76 are formed of a silicon-containing material. For example, the dielectric layers 72, 74, and 76 may include an oxide such as silicon oxide, a nitride such as silicon nitride, an oxynitride such as silicon oxynitride, the like, or a combination thereof.

FIG. 8 further illustrates the formation of bond pad vias 86 and bond pads 88 are formed in the dielectric layers 72, 74, and 76. The bond pad vias 86 and bond pads 88 are connected to the top metal 56. The bond pad vias 86 and bond pads 88 may be formed using be achieved using any suitable process, such as a single damascene process, a dual damascene process, combinations thereof, or the like. A dual damascene process will be described.

In some embodiments, a photoresist (not shown) is formed and patterned on the dielectric layer. The photoresist may be formed by spin coating or the like and may be exposed to light for patterning. The pattern of the photoresist corresponds to openings for the bond pads 88. Further, the dielectric layer 76 is patterned to form the openings using the patterned photoresist as a mask with the patterning process stopping on the dielectric layer 74. The exposed portions of the dielectric layer 76 may be removed, such as by using an acceptable etching process, such as by wet and/or dry etching.

The photoresist is removed and may be removed by an acceptable ashing or stripping process, such as using an oxygen plasma or the like. Next, another photoresist (not shown) is formed and patterned on the patterned dielectric layer 76 and in the openings through the dielectric layer 76. The photoresist may be formed by spin coating or the like and may be exposed to light for patterning. The pattern of the photoresist corresponds to openings for the bond pad vias 86. The dielectric layers 74 and 72 are patterned to form the openings using the patterned photoresist as a mask with the patterning process exposing portions of the top metal 56. The exposed portions of the dielectric layers 74 and 72 may be removed, such as by using an acceptable etching process, such as by wet and/or dry etching.

The photoresist is removed and a barrier layer 84, the bond pad vias 86, and the bond pads 88 are formed in the openings. The barrier layer 84 may be formed in the openings prior to forming bond pad vias 86 and the bond pads 88. In some embodiments, the barrier layer 84 may comprise Ti, TiN, the like, or a combination thereof. The bond pad vias 86 and the bond pads 88 may be formed by similar processes and materials as the top metal 56 and vias 54 and the description is not repeated herein. The bond pads 88 may be formed of or comprise copper, for example. Adjacent bond pads 88 have a pitch P2. In some embodiments, the pitch P2 is as small as 3.0 μm. In some embodiments, the pitch P2 is in a range from 3.0 μm to 9.0 μm.

The top surfaces of the bond pads 88 are coplanar (within process variation) with the top surface of the uppermost dielectric layer 76. The planarization is achieved through a chemical mechanical polishing (CMP) process or a mechanical grinding process.

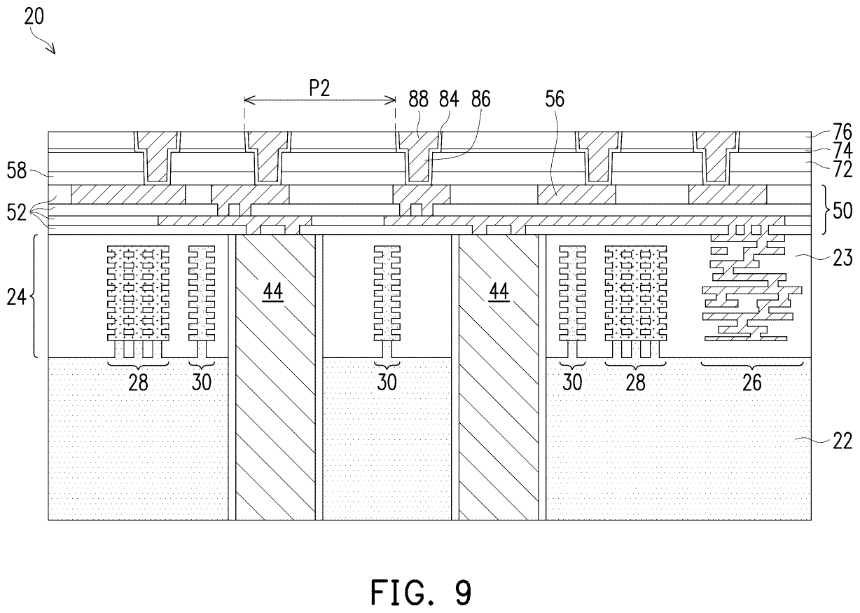

In FIG. 9, the integrated circuit die 20 is thinned by thinning the substrate 22 before the subsequent singulation process. The thinning may be performed through a planarization process such as a mechanical grinding process or a CMP process. The thinning process exposes the TSVs 44 and the liner 38. After thinning, the TSVs 44 provides electrical connection from a back side of the substrate 22 to a front side of the substrate 22 (e.g., the interconnects 24 and 50 and bond pads 88).

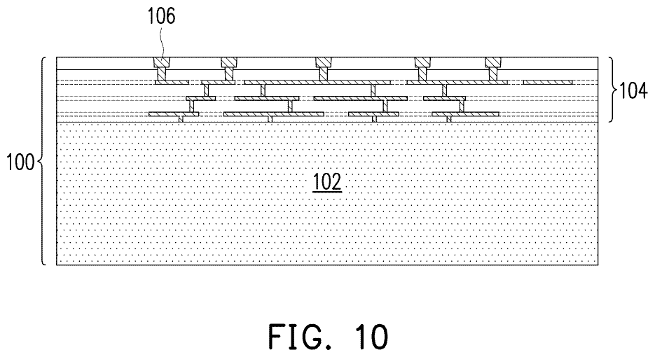

FIG. 10 illustrates a package structure 100. The package structure 100 includes a substrate 102, similar to the substrate 22 of the integrated circuit die 20, and an interconnect structure 104 including bond pads 106. The interconnect structure 104 and the bond pads 106 may be similar to the interconnect structures 24 and 50 and bond pads 88, respectively, described above and the descriptions are not repeated herein. The package structure 100 may be referred to as a die 100.

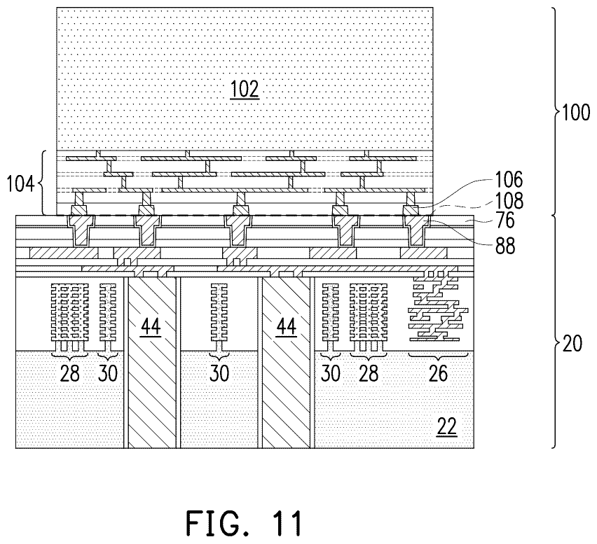

In FIG. 11, the integrated circuit die 20 is bonded to the package structure 100. The bonding of the integrated circuit die 20 to the package structure 100 may be achieved through direct bonding, in which both metal-to-metal direct bonding (between the bond pads 88 and 106) and dielectric-to-dielectric bonding (such as Si—O—Si bonding between surface dielectric layers of the integrated circuit die 20 and the package structure 100) are formed. Furthermore, there may be a single integrated circuit die 20 or a plurality of dies 20 bonded to the same package structure 100. The plurality of dies 20 bonded to the same package structure 100 may be identical to, or different from, each other to form a homogenous or a heterogeneous structure. In some embodiments, a package structure includes multiple package structures 100 and multiple integrated circuit dies 20.

The die 20 is disposed face up such that the front sides of the die 20 face the package structure 100 and the back sides of the dies 20 face away from the package structure 100. The die 20 is bonded to the package structure 100 at an interface 108. As illustrated by FIG. 11, the direct bonding process directly bonds the topmost dielectric layer of the interconnect structure 104 of the package structure 100 to the topmost dielectric layer 76 of the die 20 at the interface 108 through fusion bonding. In an embodiment, the bond between the topmost dielectric layer of the interconnect structure 104 and the topmost dielectric layer 76 of the die 20 may be an oxide-to-oxide bond. The direct bonding process further directly bonds the bond pads 88 of the die 20 to the bond pads 106 of the package structure 100 at the interface 108 through direct metal-to-metal bonding. Thus, electrical connection between the die 20 and the package structure 100 is provided by the physical connection of the bond pads 88 to the bond pads 106.

As an example, the direct bonding process starts with aligning the die 20 with the package structure 100, for example, by aligning the bond pads 88 to the bond pads 106. When the die 20 and the package structure 100 are aligned, the bond pads 88 may overlap with the corresponding bond pads 106. Next, the direct bonding includes a pre-bonding step, during which the die 20 is put in contact with the package structure 100. The direct bonding process continues with performing an anneal, for example, at a temperature between 150° C. and 400° C. for a duration between 0.5 hours and 3 hours, so that the copper in the bond pads 88 and the bond pads 106 inter-diffuses to each other, and hence the direct metal-to-metal bonding is formed.

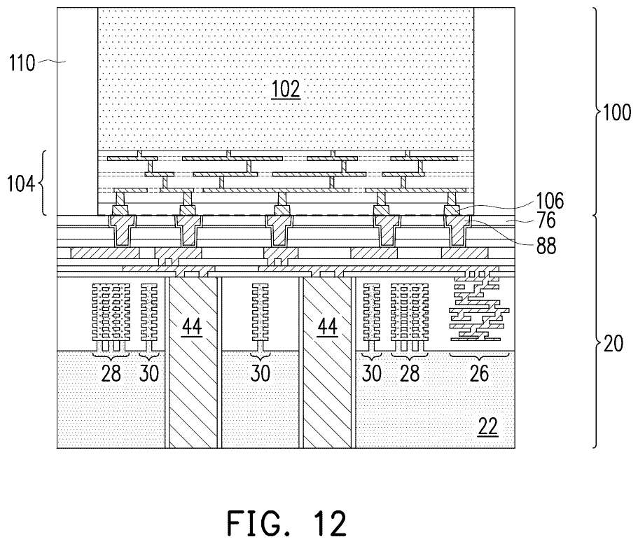

Next, as shown in FIG. 12, a gap-filling process is performed to encapsulate the package structure 100 in an encapsulant 110. After formation, the encapsulant 110 encapsulates the package structure 100 and the interconnect structure 104. The encapsulant 110 may comprise an oxide. Alternatively, the encapsulant may be a molding compound, a molding underfill, a resin, an epoxy, or the like. The encapsulant 110 may be applied by compression molding, transfer molding, or the like, and may be applied in liquid or semi-liquid form and then subsequently cured.

In some embodiments (not separately illustrated), the encapsulant 110 encapsulates the integrated circuit die 20 instead of the package structure 100. In these embodiments, the gap-filling process is performed to encapsulate the integrated circuit die 20 in the encapsulant 110. After formation, the encapsulant 110 encapsulates the integrated circuit die 20, the interconnect structure 50, and the dielectric layers 72, 74, 76. After the encapsulant 110 is deposited, a planarization process is performed to level a back-side surface of the integrated circuit die 20 with the top surface of the encapsulant 110 and to expose the TSVs 44. After the encapsulant 110 is deposited, a planarization process is performed to level a back-side surface of the integrated circuit die 20 with the top surface of the encapsulant 110 and to expose the TSVs 44. Surfaces of the TSVs 44, the substrate 22, and the encapsulant 110 are substantially coplanar after the planarization process within process variations. The planarization process may be, for example, a chemical-mechanical polish (CMP), a grinding process, or the like. In some embodiments, the planarization may be omitted, for example, if the TSVs 44 are already exposed.

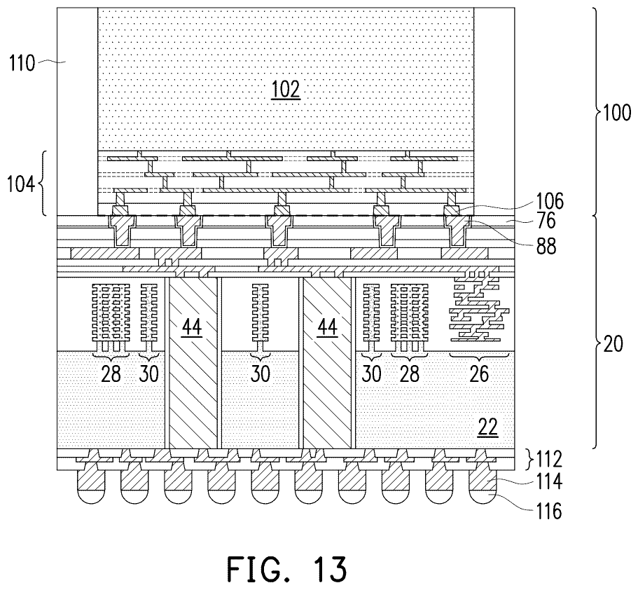

In FIG. 13, a redistribution structure 112 is formed on the TSVs 44 and the dies 20. The redistribution structure 112 may include redistribution lines (RDLs), such as metal traces (or metal lines), and vias underlying and connected to the metal traces. The redistribution lines of the redistribution structure 112 are physically and electrically connected to the TSVs 44 of the dies 20.

In accordance with some embodiments of the present disclosure, the RDLs are formed through plating processes, wherein each of the RDLs includes a seed layer (not shown) and a plated metallic material over the seed layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the RDLs. The patterning forms openings through the photoresist to expose the seed layer. A conductive material is formed in the openings of the photoresist and on the exposed portions of the seed layer. The conductive material may be formed by plating, such as electroplating or electroless plating, or the like. The seed layer and the plated metallic material may be formed of the same material or different materials. The conductive material may be a metal, like copper, titanium, tungsten, aluminum, or the like. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet and/or dry etching. The remaining portions of the seed layer and conductive material form the RDLs.

Dielectric or passivation layers may be formed over each layer of the metal traces. In some embodiments, the dielectric or passivation layers are formed of a polymer, which may be a photo-sensitive material such as PBO, polyimide, BCB, or the like, that may be patterned using a lithography mask. In other embodiments, the dielectric or passivation layers are formed of a nitride such as silicon nitride; an oxide such as silicon oxide, PSG, BSG, BPSG; or the like. The dielectric or passivation layers may be formed by spin coating, lamination, CVD, the like, or a combination thereof.

Openings may be formed in the top dielectric or passivation layer with a patterning process, exposing some or all of the top metal layer of the redistribution structure 112. The patterning process may be an acceptable process, such as by exposing the dielectric or passivation layer to light when the dielectric layer is a photo-sensitive material or by etching using, for example, an anisotropic etch.

The redistribution structure 112 is illustrated as an example. More or fewer dielectric layers and metallization layers than illustrated may be formed in the redistribution structure 112 by repeating or omitting the steps previously described.

In FIG. 13, under-bump metallizations (UBMs) 114 are formed for external connection to the redistribution structure 112. The UBMs 114 have bump portions on and extending along the top surface of the upper dielectric layer of the redistribution structure 112, and have via portions extending through the upper dielectric layer of the redistribution structure 112 to physically and electrically couple the upper metallization layer of the redistribution structure 112. As a result, the UBMs 114 are electrically connected to the dies 20 (e.g., the interconnects 50 and the TSVs 44). The UBMs 114 may be formed of the same material as the metallization layers of the redistribution structure 112, and may be formed by a similar process. In some embodiments, the UBMs 114 have a different size (such as a greater size) than the metallization layers of the redistribution structure 140.

Conductive connectors 116 are formed on the UBMs 114. The conductive connectors 116 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 116 may include a conductive material such as solder, copper, aluminum, gold, nickel, silver, palladium, tin, the like, or a combination thereof. In some embodiments, the conductive connectors 116 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the conductive connectors 116 comprise metal pillars (such as copper pillars) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

In some embodiments, passive devices (not shown) (e.g., surface mount devices (SMDs)) may be attached to the package component (e.g., bonded to the UBMs 114 or the metallization layers of the redistribution structure 112). The passive devices may be bonded to a same surface of the package component as the conductive connectors 116.

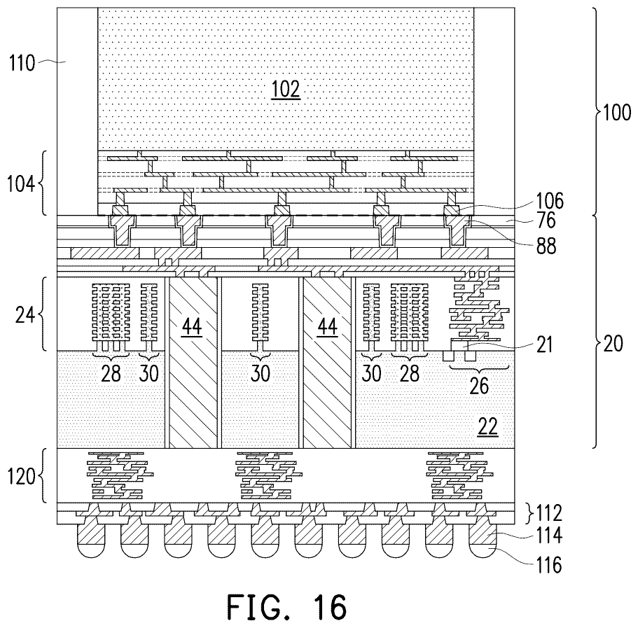

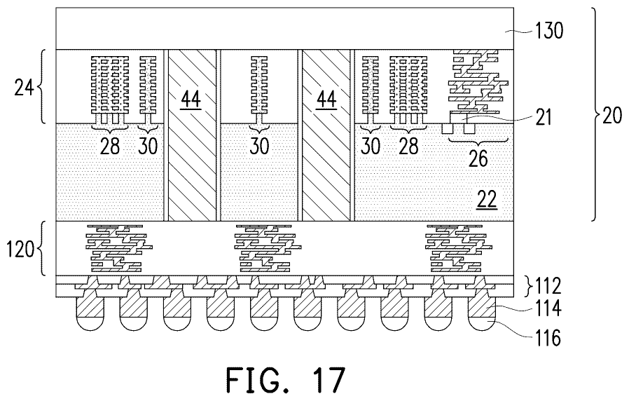

In some embodiments, the integrated circuit die 20 includes a back-side interconnect structure 120 (see, e.g., FIGS. 16 and 17). In FIGS. 16 and 17, the back-side interconnect structure 120 includes metallization patterns in one or more dielectric layers and is similar to the interconnect structure 24 described above. In these embodiments, the backside interconnect structure 120 can be formed on the backside of the thinned substrate 22 and be connected to the TSVs 44 or other conductive elements extending into the substrate 22. The backside interconnect structure can be electrically connected to the active devices 21 of the integrated circuit die 20 and the metallization patterns of the interconnect 50 through the TSVs 44 or other conductive elements extending into the substrate 22. For example, the back-side interconnect structure 120 can be electrically connected to source/drain regions of active devices 21. In some embodiment, the TSVs 44 can connect to RDL 112 directly. The interconnect structure 120 and TSVs 44 can connect to RDL 112 respectively, and further electrically connect to conductive connector 116.

The embodiment illustrated in FIG. 13 includes dies 20 and 100 bonded together in a face-to-face configuration. Other embodiments are also contemplated in the present disclosure. For example, in FIG. 17, the interconnect 50 and the bond pad vias 86 and bond pads 88 are omitted and replaced with a heat dissipation structure 130. The heat dissipation structure 130 may include one or more layers of a high thermal conductivity material (having a thermal conductivity greater than 10 Watts/meter Kelvin (W/m·K), also referred to as high-kappa material or high-K material), such as a suitable nitride (e.g., AlN, BN, or the like), a suitable metal oxide (e.g., Y₂O₂, Y₃A₁₅O₁₂ (yttrium aluminum garnet, YAG), Al₂O₂, BeO, or the like), a suitable carbide (e.g., SiC, graphene, diamond-like-carbon (DLC), diamond, or the like), combinations thereof, or the like. The TSVs 44 and the guard rings 30 can be connected to the heat dissipation structure 130. Further, the integrated circuit die 20 may be coupled to external devices (e.g., die 100) through the backside interconnect structure 120 (when present). In some embodiments, a lid or heat sink structure may be over and/or attached to the heat dissipation structure 130.

In some embodiments, signals maybe transmitted through the backside of the die 20 by the TSVs 44. In some embodiments, the backside interconnect structure 120 can connect to devices 21 directly. Further, the signals maybe be transmitted to the backside of the die 20 utilizing various paths. In some embodiments, signals can be transmitted through the path (front-side interconnect structure 24/26-->TSV 44-->redistribution structure 112/-->connectors 114/116). In some embodiments, signals can be transmitted through the path (backside interconnect 120-->redistribution structure 112-->connectors 114/116).

In each of the above-described embodiments, the redistribution structure 112 may be omitted and the TSVs 44 connect directly to the UBMs 114. The UBMs 114 may be formed to directly contact the exposed ends of the TSVs 44.

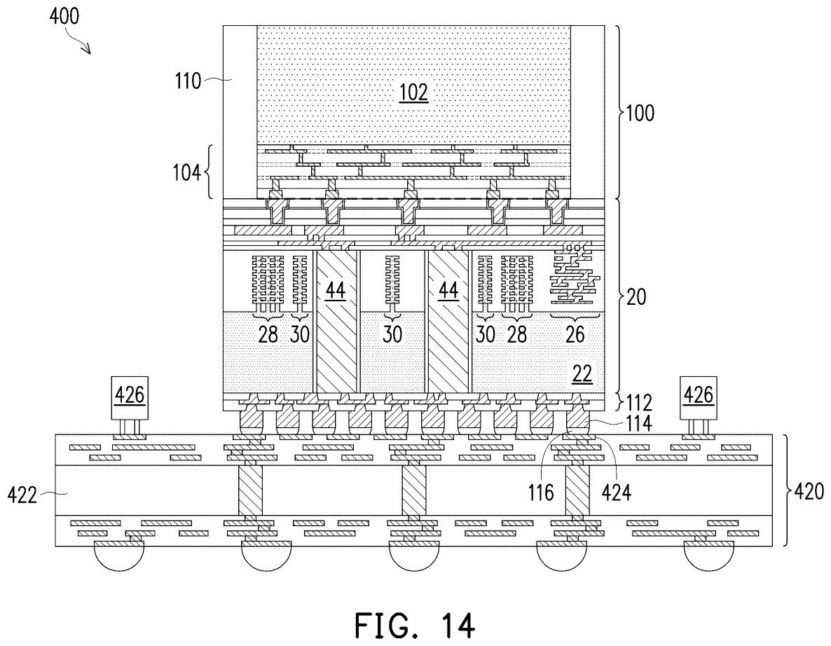

In FIG. 14, the package component of FIG. 13 is attached to a package substrate 420 using the conductive connectors 116 to form a package structure 400. The package substrate 420 includes a substrate core 422, which may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations thereof, or the like, may also be used. Additionally, the substrate core 422 may be a SOI substrate. Generally, an SOI substrate includes a layer of a semiconductor material such as epitaxial silicon, germanium, silicon germanium, SOI, SGOI, or combinations thereof. In another embodiment, the substrate core 422 is an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for the substrate core 422.

The substrate core 422 may include active and passive devices (not separately illustrated). Devices such as transistors, capacitors, resistors, combinations thereof, and the like may be used to generate the structural and functional requirements of the design for the system. The devices may be formed using any suitable methods.

The substrate core 422 may also include metallization layers and vias, and bond pads 424 over the metallization layers and vias. The metallization layers may be formed over the active and passive devices and are designed to connect the various devices to form functional circuitry. The metallization layers may be formed of alternating layers of dielectric material (e.g., low-k dielectric material) and conductive material (e.g., copper) with vias interconnecting the layers of conductive material, and may be formed through any suitable process (such as deposition, damascene, or the like). In some embodiments, the substrate core 422 is substantially free of active and passive devices.

The conductive connectors 116 are reflowed to attach the metallizations 114 to the bond pads 424. The conductive connectors 116 connect the package component, including the RDL 112 and interconnect structure 50, to the package substrate 420, including metallization layers of the substrate core 422. Thus, the package substrate 420 is electrically connected to the die 20. In some embodiments, passive devices 426 (e.g., SMDs) may be attached to the package substrate 420, e.g., to the bond pads 424.

In some embodiments, an underfill (not shown) is formed between the package component and the package substrate 420, surrounding the conductive connectors 116. The underfill may be formed by a capillary flow process after the package component is attached or may be formed by any suitable deposition method before the package component is attached.

FIGS. 15A, 15B, 15C, and 15D illustrate a cross-sectional view and plan views of the integrated circuit die 20 in accordance with some embodiments. These embodiments include dummy metallization pattern 28 between adjacent TSVs 44 in a TSV cluster 46. Details regarding this embodiment that are similar to those for the previously described embodiment will not be repeated herein.

In these embodiments, the dummy metallization patterns 28 are between adjacent TSVs 44 in the TSV cluster 46. For example, in FIG. 15B, the dummy metallization pattern 28 extends in a ‘+’ shape between the four TSVs 44. In this example, the guard ring 30 extends on the outer edges of the TSV cluster 46 and not between the TSVs 44 of the TSV cluster 46. In this embodiment, the dummy metallization pattern 28 extends from the guard ring 30 without gaps between the guard ring 30 and the dummy metallization pattern 28.

FIG. 15C is similar to FIG. 15B and it further has gaps 502 between the guard ring 30 and the dummy metallization pattern 28 and at the crossing points of the dummy metallization pattern 28. In this embodiment, there are two gaps 502 at the crossing point of the dummy metallization pattern 28. By having the gaps 502 where the dummy metallization pattern 28 would meet other structures (e.g., 28 or 30) at right angles, the uniformity of the dummy metallization pattern 28 is improved as it is difficult for a plating process to accurately grow structures in corners or right angles.

FIG. 15D is similar to FIG. 15C and it has a single gap 502 in the middle of the ‘+’ shape between the dummy metallization pattern 28 portions. In this embodiment, the gaps 502 are at places where the dummy metallization pattern 28 would meet with structures at right angles.

Although FIGS. 15B-D illustrate TSV clusters 46 with four TSVs 44, these embodiments are not limited to those numbers of TSVs 44 per TSV cluster 46 and each may have more or less TSVs 44 per TSV cluster.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or the 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments discussed herein may be discussed in a specific context, namely a through substrate via (TSV) cluster that has reduced pitch between adjacent TSVs. In some embodiments, the TSV cluster has a merged guard ring wall between adjacent TSVs. In some embodiments, a dummy interconnect structure is between adjacent TSVs of the TSV cluster instead of the merged guard ring wall. By having the merged guard ring wall or the dummy interconnect structure between adjacent TSVs of the TSV cluster, the pitch between adjacent TSVs can be reduced. Thus, the total area consumed by the TSV cluster is reduced and more area can be used for other functionality of the device, or the device size can be reduced. In some embodiments, the disclosed TSV cluster may be applied to a device (e.g., a chip or die) or a package (e.g., system on integrated chip (SoIC), a chip-on-wafer (CoW) package structure, or a wafer-on-wafer (WoW) package structure). By reducing the pitch between the adjacent TSVs in a TSV cluster, the performance, power, and area cost of the device is improved. For example, in a 2×2 TSV cluster, the area cost with the disclosed TSV cluster is reduced by 25%-35% as compared to a conventional TSV structure.

An embodiment includes a device, the device including a first die including a first surface and a second surface opposite the first surface. The first die includes a plurality of through substrate vias (TSVs) exposed from the second surface of the first die. The device also includes a guard ring surrounding the plurality of TSVs. The device also includes a dummy metallization pattern surrounding the guard ring.

Embodiments may include one or more of the following features. The device where the guard ring extends to between the plurality of TSVs. The guard ring surrounds the plurality of TSVs and extends between the plurality of TSVs is a continuous guard ring. The device further including an active metallization pattern connected to active devices in the first die. The first die include a substrate, the first surface being on a first side of the substrate, a first interconnect structure on the first side of the substrate, the guard ring, the dummy metallization pattern, and the active metallization pattern being in the first interconnect structure, and a second interconnect structure on a second side of the substrate, metallization patterns of the second interconnect structure being electrically coupled to at least one of the plurality of TSVs. The device where the first die further includes a high-kappa material on the first interconnect structure and the plurality of TSVs. The device further including a second die bonded to the first surface of the first die, the first surface comprising bond pads. The dummy metallization pattern extends between the plurality of TSVs. The dummy metallization pattern extending between the plurality of TSVs is physically connects to the guard ring surrounding the plurality of TSVs. Gaps separate the dummy metallization pattern extending between the plurality of TSVs and the guard ring. A gap separates the dummy metallization pattern at a crossing point between the plurality of TSVs. The guard ring does not extend between the plurality of TSVs.

An embodiment includes a method, the method including forming a first die including a first surface and a second surface opposite the first surface, where forming the first die includes forming a first interconnect structure over a first substrate, the first interconnect structure including an active metallization pattern, a guard ring, and a dummy metallization pattern. The method also includes forming through substrate vias (TSVs) through the first interconnect structure and the first substrate, the guard ring surrounding the TSVs in the first interconnect structure, the dummy metallization pattern surrounding the guard ring. The method also includes forming bond pads over the first interconnect structure and connected to the TSVs and the active metallization pattern of the first interconnect structure, the bond pads being on the first surface of the first die, the TSVs being exposed at the second surface of the first die. The method also includes forming a second die including a first surface and a second surface opposite the first surface. The method also includes bonding the first surface of the first die to the first surface of the second die.

Embodiments may include one or more of the following features. The method where the guard ring extends between the TSVs. The guard ring that surrounds the TSVs and extends between the TSVs is a continuous guard ring. The dummy metallization pattern extends between the TSVs. Gaps separate the dummy metallization pattern extending between the TSVs and the guard ring. The guard ring does not extend between the TSVs. The method further including forming a redistribution structure on the second surface of the first die, the redistribution structure being electrically connected to the TSVs, forming conductive connectors on the redistribution structure, bonding the first die to a package substrate with the conductive connectors.

An embodiment includes a method, the method including forming a first die including a first surface and a second surface opposite the first surface, where forming the first die includes forming a first interconnect structure over a first substrate, the first interconnect structure including an active metallization pattern, a guard ring, and a dummy metallization pattern. The method also includes forming through substrate vias (TSVs) through the first interconnect structure and the first substrate, the guard ring being a continuous structure surrounding and extending between the TSVs in the first interconnect structure, the dummy metallization pattern surrounding the guard ring. The method also includes forming a second interconnect structure on the first substrate, the second interconnect structure being on an opposite side of the first substrate from the first interconnect structure.

Embodiments may include one or more of the following features. The method where the active metallization pattern is connected to active devices in the first die.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first die comprising a first surface and a second surface opposite the first surface;
a plurality of through substrate vias (TSVs) exposed from the second surface of the first die;
a continuous guard ring surrounding and extending between the plurality of TSVs;
a dummy metallization pattern surrounding the continuous guard ring;
a first interconnect structure on the first die, wherein the continuous guard ring and the dummy metallization pattern are in the first interconnect structure; and
an active metallization pattern in the first interconnect structure and connected to active devices in the first die.

2. The semiconductor device of claim 1, wherein the first die further comprises a substrate, the first surface being on a first side of the substrate, and the first interconnect structure being on the first side of the substrate.

3. The semiconductor device of claim 2, further comprising a second interconnect structure on a second side of the substrate, metallization patterns of the second interconnect structure being electrically coupled to at least one of the plurality of TSVs.

4. The semiconductor device of claim 1, further comprising a second die bonded to the first surface of the first die, the first surface comprising bond pads.

5. The semiconductor device of claim 1, wherein the dummy metallization pattern extends between the plurality of TSVs.

6. The semiconductor device of claim 5, wherein the dummy metallization pattern extending between the plurality of TSVs physically connects to the continuous guard ring surrounding the plurality of TSVs.

7. The semiconductor device of claim 5, wherein gaps separate the dummy metallization pattern extending between the plurality of TSVs and the continuous guard ring.

8. A method comprising:
forming a first die comprising a first surface and a second surface opposite the first surface, wherein forming the first die comprises:
forming a first interconnect structure over a first substrate, the first interconnect structure comprising an active metallization pattern, a continuous guard ring, and a dummy metallization pattern;
forming through substrate vias (TSVs) through the first interconnect structure and the first substrate, the continuous guard ring surrounding and extending between the TSVs in the first interconnect structure, the dummy metallization pattern surrounding the continuous guard ring;
forming bond pads over the first interconnect structure and connected to the TSVs and the active metallization pattern of the first interconnect structure, the bond pads being on the first surface of the first die, the TSVs being exposed at the second surface of the first die;
forming a second die comprising a first surface and a second surface opposite the first surface;
bonding the first surface of the first die to the first surface of the second die;
forming a redistribution structure on the second surface of the first die, the redistribution structure being electrically connected to the TSVs;
forming conductive connectors on the redistribution structure; and
bonding the first die to a package substrate with the conductive connectors.

9. The method of claim 8, wherein the dummy metallization pattern extends between the TSVs.

10. The method of claim 9, wherein gaps separate the dummy metallization pattern extending between the TSVs and the continuous guard ring.

11. The method of claim 8, further comprising forming a second interconnect structure on the first substrate, the second interconnect structure being on an opposite side of the first substrate from the first interconnect structure.

12. The method of claim 8, wherein the active metallization pattern is connected to active devices in the first die.

13. The method of claim 8, further comprising forming an underfill between the first die and the package substrate, the underfill surrounding the conductive connectors.

14. A semiconductor package comprising:
a first die comprising:
a plurality of through substrate vias (TSVs);
a continuous guard ring surrounding and extending between the TSVs;
a first interconnect structure comprising the continuous guard ring;
a heat dissipation structure on a first side of the first die;
a backside interconnect structure on a second side of the first die opposite the first side, wherein the TSVs are connected to the heat dissipation structure; and
a second die bonded to the second side of the first die.

15. The semiconductor package of claim 14, wherein the heat dissipation structure comprises a high thermal conductivity material.

16. The semiconductor package of claim 15, wherein the high thermal conductivity material is selected from the group consisting of aluminum nitride, boron nitride, yttrium oxide, yttrium aluminum garnet, aluminum oxide, beryllium oxide, silicon carbide, graphene, diamond-like-carbon, and diamond.

17. The semiconductor package of claim 14, further comprising a dummy metallization pattern surrounding the continuous guard ring.

18. The semiconductor package of claim 17, wherein the dummy metallization pattern extends between the TSVs.

19. The semiconductor package of claim 14, wherein the backside interconnect structure is electrically connected to active devices in the first die through the TSVs.

20. The semiconductor package of claim 14, further comprising a redistribution structure on the first side of the first die, the redistribution structure being electrically connected to the TSVs.
